(19) United States
(12) Patent Application Publication
(10) Pub. No.: US 2025/0389014 A1
(43) Pub. Date: Dec. 25, 2025

(54) SUBSTRATE SUPPORT APPARATUS AND DEPOSITION SYSTEM INCLUDING THE SAME

(71) Applicant: SAMSUNG DISPLAY CO., LTD., YONGIN-SI (KR)

(72) Inventors: YONGWOO JEONG, Yongin-si (KR); CHANGWOOK SEO, Yongin-si (KR); BYUNGHUN SUNG, Yongin-si (KR); SUNGYONG LEE, Yongin-si (KR)

(21) Appl. No.: 19/060,850

(22) Filed: Feb. 24, 2025

(30) Foreign Application Priority Data
Jun. 25, 2024 (KR) 10-2024-0083092

(51) Int. Cl. C23C 14/50; H10K 71/16

(52) U.S. Cl. CPC C23C 14/505; H10K 71/164; H10K 71/166

(57) ABSTRACT

A substrate support apparatus includes: a substrate main holder supporting three sides of four sides of a substrate; and a substrate sub-holder supporting a remaining side of the four sides of the substrate; wherein the substrate sub-holder includes: a sub-support part that contacts the remaining side and supports the remaining side; a sub-lifting part that moves the sub-support part along a vertical direction; and a rotation part that rotates the sub-support part at a predetermined angle.

### CROSS-REFERENCE TO RELATED APPLICATION

This application claims priority under 35 U.S.C. § 119 to Korean Patent Application No. 10-2024-0083092 filed at the Korean Intellectual Property Office on Jun. 25, 2024, the disclosure of which is incorporated by reference herein in its entirety.

### TECHNICAL FIELD

Embodiments of the present invention relate to a substrate support apparatus and a deposition system including the substrate support apparatus.

### DISCUSSION OF THE RELATED ART

In general, flat panel displays such as organic light emitting diode (OLED) displays are manufactured by undergoing a series of processes including, for example, a deposition process where metal thin films, organic thin films, and the like are deposited in a predetermined pattern on a substrate.

Typically, this deposition process may be performed by transporting the substrate into a vacuum chamber. However, as the area of the substrate increases, the weight of the substrate increases, making it difficult to transport and support the substrate.

Additionally, the substrate support apparatus supports the ends of the four sides of the substrate so that the deposition surface of the substrate is exposed. However, as the size of the substrate increases, when the ends of the four sides of the substrate are supported, sagging may occur in the center of the substrate, which may cause errors in the alignment process between the substrate and a mask. Accordingly, the precision of deposition may decrease and the manufacturing yield of the flat panel display device may decrease.

### SUMMARY

According to an embodiment of the present invention, a substrate support apparatus includes: a substrate main holder supporting three sides of four sides of a substrate; and a substrate sub-holder supporting a remaining side of the four sides of the substrate; wherein the substrate sub-holder includes: a sub-support part that contacts the remaining side and supports the remaining side; a sub-lifting part that moves the sub-support part along a vertical direction; and a rotation part that rotates the sub-support part at a predetermined angle.

In an embodiment of the present invention, the three sides of the substrate that are supported by the substrate main holder include a first short side, a second short side, and a first long side, wherein the first short side and the second short side face each other, and the first long side connect the first short side and the second short side to each other, and the remaining side of the substrate that is supported by the substrate sub-holder includes a second long side facing the first long side.

In an embodiment of the present invention, the sub-lifting part includes: a sub-lifting drive motor that provides a lifting driving force to move the sub-support part along the vertical direction; a sub-lifting drive shaft connected to the sub-lifting drive motor; and a lifting connection part connecting the sub-support part and the sub-lifting drive shaft to each other.

In an embodiment of the present invention, the lifting connection part includes: a lifting connection body that protrudes from the sub-support part and has a rotating hole; and a lifting bearing installed at an end of the lifting drive shaft and inserted into the rotating hole to rotate.

In an embodiment of the present invention, the rotation part includes: a rotation drive motor that provides a rotational driving force to rotate the sub-support part to a predetermined angle; a rotation drive shaft connected to the rotation drive motor; and a rotation connection part connecting the sub-support part and the rotation drive shaft to each other.

In an embodiment of the present invention, the rotation connection part includes: a rotation connection body that protrudes from the sub-support part and has a sliding hole; and a rotation bearing installed at the end of the rotation drive shaft and inserted into the sliding hole to slide within the sliding hole.

In an embodiment of the present invention, the substrate main holder includes; a main support part that has a rectangular or square annular shape and is in contact with the four sides of the substrate; and a main lifting part that moves the main support part along the vertical direction.

In an embodiment of the present invention, the main support part includes: a first main support frame and a second main support frame facing each other; a third main support frame that is longer than the first main support frame and connects the first main support frame and the second main support frame to each other; and a fourth main support frame facing the third main support frame and having a cutting part where the substrate sub-holder is disposed.

In an embodiment of the present invention, the main lifting part includes: a first main lifting part that moves the first main support frame along the vertical direction; a second main lifting part that moves the second main support frame along the vertical direction; and a third main lifting part that moves the third main support frame along the vertical direction; and the first main lifting part and the second main lifting part are disposed facing each other.

In an embodiment of the present invention, a deposition system includes: a deposition chamber that performs a deposition process on a substrate; a transfer device that transfers the substrate into the deposition chamber; and a substrate support apparatus that supports the substrate that is carried into the deposition chamber by the transfer device, wherein the substrate support apparatus includes: a substrate main holder supporting three sides of four sides of the substrate; and a substrate sub-holder supporting a remaining side of the four sides of the substrate; wherein the substrate sub-holder includes: a sub-support part that contacts the remaining side and supports the remaining side; a sub-lifting part that moves the sub-support part along a vertical direction; and a rotation part that rotates the sub-support part at a predetermined angle.

In an embodiment of the present invention, the three sides of the substrate that are supported by the substrate main holder include a first short side, a second short side, and a first long side, wherein the first short side and the second short side face each other, and the first long side connects the first short side and the second short side to each other, and the remaining side of the substrate that is supported by the substrate sub-holder includes a second long side facing the first long side.

In an embodiment of the present invention, the sub-lifting part includes: a sub-lifting drive motor that provides a lifting driving force to move the sub-support part along the vertical direction; a sub-lifting drive shaft connected to the sub-lifting drive motor; and a lifting connection part connecting the sub-support part and the sub-lifting drive shaft to each other.

In an embodiment of the present invention, the lifting connection part includes: a lifting connection body that protrudes from the sub-support part and has a rotation hole; and a lifting bearing installed at an end of the sub-lifting drive shaft and inserted into the rotation hole to rotate.

In an embodiment of the present invention, the rotation part includes: a rotation drive motor that provides a rotational driving force to rotate the sub-support part to a predetermined angle; a rotation drive shaft connected to the rotation drive motor; and a rotation connection part connecting the sub-support part and the rotation drive shaft to each other.

In an embodiment of the present invention, the rotation connection part includes: a rotation connection body that protrudes from the sub-support part and has a sliding hole; and a rotation bearing installed at end of the rotation drive shaft and inserted into the sliding hole to slide within the sliding hole.

In an embodiment of the present invention, the substrate main holder includes: a main support part that has a rectangular or square annular shape and is in contact with the four sides of the substrate; and a main lifting part that moves the main support part along the vertical direction, the main support part includes: a first main support frame and a second main support frame facing each other; a third main support frame that is longer than the first main support frame and connects the first main support frame and the second main support frame to each other; and a fourth main support frame facing the third main support frame and having a cutting part where the substrate sub-holder is disposed.

In an embodiment of the present invention, the main lifting part includes: a first main lifting part that moves the first main support frame along the vertical direction; a second main lifting part that moves the second main support frame along the vertical direction; and a third main lifting part that moves the third main support frame along the vertical direction, and the first main lifting part and the second main lifting part are disposed facing each other.

In an embodiment of the present invention, the first main lifting part includes a first main lifting drive motor and a first main lifting driving shaft, wherein the first main lifting drive motor provides a lifting driving force to raise and lower the first main support frame, wherein the first main lifting drive shaft is connected to the first main lifting drive motor, and the second main lifting part includes a second main lifting drive motor and a second main lifting drive shaft, wherein the second main lifting drive motor provides a lifting driving force to raise and lower the second main support frame, wherein the second main lifting drive shaft is connected to the second main lifting drive motor.

In an embodiment of the present invention, an end effector of the transfer device carries the substrate through the cutting part, the main support part supports the first short side, the second short side, and the first long side of the substrate, and the main lifting part moves the substrate along the vertical direction, and the sub-support part supports a second long side of the substrate, and the sub-lifting part and the rotation part move the sub-support part to come into contact the second long side of the substrate.

According to an embodiment of the present invention, a deposition system includes: a deposition chamber that performs a deposition process on a substrate; and a substrate support apparatus that supports the substrate that is within the deposition chamber, wherein the substrate support apparatus includes: a substrate main holder supporting three sides of four sides of the substrate; and a substrate sub-holder supporting a remaining side of the four sides of the substrate; wherein the substrate sub-holder includes: a sub-support part that supports the remaining side of the substrate; a sub-lifting part that moves the sub-support part along a vertical direction; and a rotation part connected to the sub-support part and rotating the sub-support part, wherein the sub-lifting part includes: a sub-lifting drive motor that moves the sub-support part along the vertical direction; and a sub-lifting drive shaft connected to the sub-lifting drive motor and the sub-support part, wherein the rotation part includes: a rotation drive motor that provides a rotational driving force to rotate the sub-support part to a predetermined angle; and a rotation drive shaft connected to the rotation drive motor and the sub-support part.

### BRIEF DESCRIPTION OF THE DRAWINGS

FIG. 1 is a schematic diagram of a deposition system according to an embodiment of the present inventive concept.

FIG. 2 is a perspective view of the substrate support apparatus of FIG. 1.

FIG. 3 is a perspective view of the substrate sub-holder of FIG. 2.

FIG. 4 is an enlarged perspective view of portion A of FIG. 3.

FIGS. 5, 6, 7, 8 and 9 are schematic side views sequentially illustrating the operation of the substrate support apparatus in the deposition system of FIG. 1.

### DETAILED DESCRIPTION OF THE EMBODIMENTS

Hereinafter, with reference to the attached drawings, various embodiments of the present invention will be described in detail so that those skilled in the art may easily implement the present invention. The invention may be implemented in many different forms and is not limited to the embodiments described herein.

In order to clearly explain the present invention, identical or similar components are assigned the same reference numerals throughout the specification and drawings, and redundant descriptions may be omitted.

In the drawings, various thicknesses, lengths, and angles are shown and while the arrangement shown does indeed represent an embodiment of the present invention, it is to be understood that modifications of the various thicknesses, lengths, and angles may be possible within the spirit and scope of the present invention and the present invention is not necessarily limited to the particular thicknesses, lengths, and angles shown.

Additionally, when a part of a layer, membrane, region, or plate is said to be “above” or “on” another part, this includes not only cases where it is “directly above” another part, but also cases where there is another part therebetween. In contrast, when an element is referred to as being “directly on” another element, there are no intervening elements present. In addition, being “above” or “on” a reference part means being disposed above or below the reference part, and does not necessarily mean being disposed “above” or “on” it in the direction opposite to gravity.

In addition, throughout the specification, when reference is made to “on a plane,” this means when the target part is viewed from above, and when reference is made to “in a cross-section,” this means when a cross-section of the target portion is cut vertically and viewed from the side.

Next, the substrate support apparatus and a deposition system including the substrate support apparatus according to an embodiment of the present invention will be described in detail with reference to the accompanying drawings. Further, the substrate support apparatus according to an embodiment of the present invention may prevent sagging of a substrate with a large area when inputting the substrate into the deposition system and while the substrate is within the deposition system.

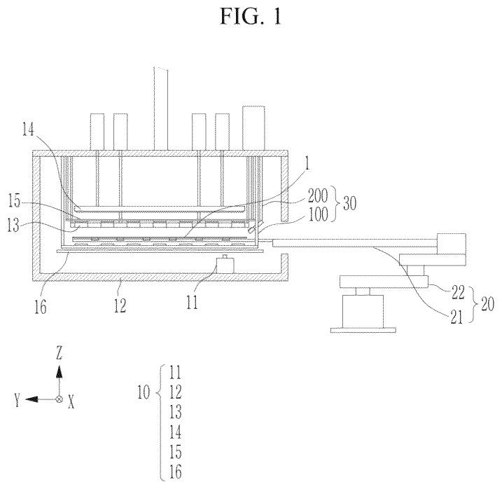

FIG. 1 is a schematic diagram of a deposition system according to an embodiment of the present invention.

As shown in FIG. 1, the deposition system according to an embodiment of the present invention includes a deposition chamber 10, a transport device 20, and the substrate support apparatus 30.

The deposition chamber 10 may perform a deposition process on a substrate 1. The deposition chamber 10 may include an evaporation source 11, a chamber body 12, an electrostatic chuck 13, a magnet plate 14, a clamp 15, and a mask 16.

The evaporation source 11 may be heated to spray evaporation particles in the gas phase.

The chamber body 12 has the evaporation source 11 installed therein, and may maintain a vacuum atmosphere for deposition of evaporation particles. A substrate 1 may be transferred in and out of the chamber body 12. An opening 12a may be installed on the side wall of the chamber body 12, and the substrate 1 may be brought in and out of the chamber body 12 through the opening 12a.

The electrostatic chuck 13 may lower the substrate 1 to the mask 16 by adsorbing and fixing the substrate 1 with static electricity in a vacuum atmosphere.

A magnet plate 14 may be disposed on the electrostatic chuck 13. The magnet plate 14 may close the distance from the electrostatic chuck 13 and bring the mask 16 into close contact with the substrate 1 through magnetic force.

If the electrostatic chuck 13 does not function properly during the deposition process, the clamp 15 may hold the substrate 1 and stably discharge it to the outside. Additionally, if the electrostatic chuck 13 is turned off and the substrate 1 does not separate from the electrostatic chuck 13, the clamp 15 may physically separate the substrate 1 from the electrostatic chuck 13.

The mask 16 has a predetermined mask pattern, and a deposition pattern may be formed on the substrate 1 by using this mask pattern of the mask 16.

The transport device 20 may be spaced apart from the deposition chamber 10. The transport device 20 supports the substrate 1 and may transport the substrate 1 into the deposition chamber 10. The transport device 20 may include an end effector 21 that supports and contacts the substrate 1, and a robot arm 22 for transporting the end effector 21 into the interior of the chamber body 12.

The substrate support apparatus 30 may support the substrate 1 that is carried into a chamber main body 12 by the transport device 20. The substrate support apparatus 30 may support the ends of the four sides of the substrate 1 so that the gaseous evaporated particles that are ejected from the evaporation source 11 are deposited onto the substrate 1.

Since the transport device 20, which brings the substrate 1 in and out of the chamber body 12, interferes with a portion of the main support part 110 of the substrate main holder 100 of the substrate support apparatus 30, an incision is formed in a portion of the main support part 110 to allow the transport device 20 to pass therethrough. At this time, since the main support part 110 might not support any one of the four sides of the substrate 1, sagging may occur in the substrate 1. For example, when the substrate 1 is input into the chamber body 12 toward the long sides 1La and 1Lb of the four sides of the substrate 1, the main support part 110 might not support either of the long sides 1La and 1Lb of the substrate 1, and in the case of large area substrates, sagging is more likely to occur.

The substrate support apparatus 30, which may prevent sagging of the substrate 1, will be described in more detail below with reference to the drawings.

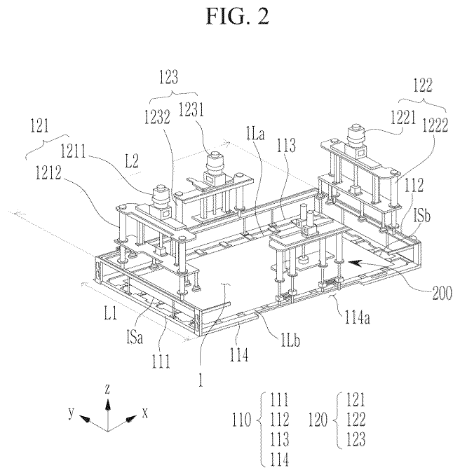

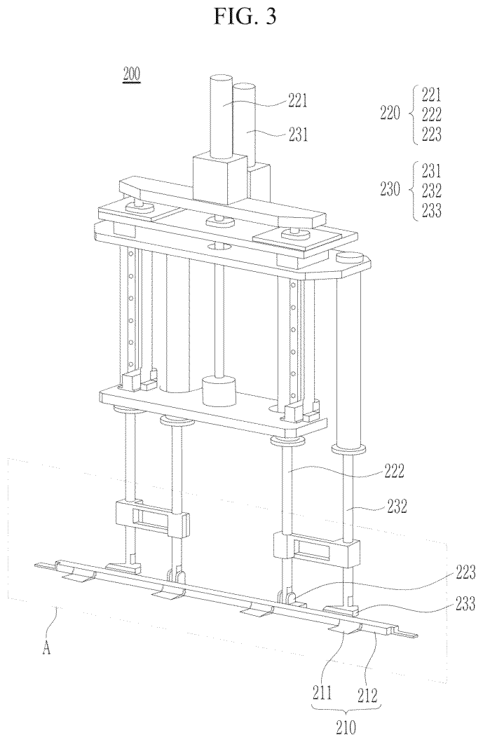

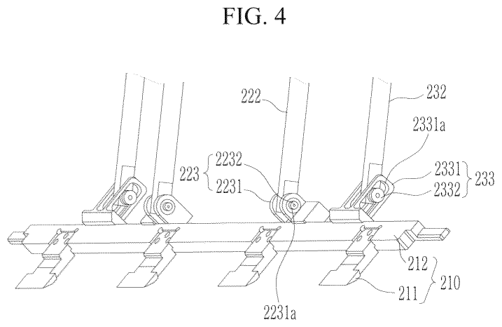

FIG. 2 is a perspective view of the substrate support apparatus of FIG. 1. FIG. 3 is a perspective view of the substrate sub-holder of FIG. 2, and FIG. 4 is an enlarged perspective view of portion A of FIG. 3.

As shown in FIGS. 2 to 4, the substrate support apparatus 30 includes the substrate main holder 100 and the substrate sub-holder 200.

The substrate main holder 100 may support three of the four sides of the substrate 1.

The substrate 1 may include a first short side 1Sa, a second short side 1Sb, a first long side 1La, and a second long side 1Lb. The first short side 1Sa and the second short side 1Sb face each other. The first long side 1La and the second long side 1Lb face each other and connect the first short side 1Sa and the second short side 1Sb to each other. Here, the substrate main holder 100 may support the first short side 1Sa, the second short side 1Sb, and the first long side 1La.

The substrate main holder 100 may include the main support part 110 and a main lifting part 120.

The main support part 110 has a rectangular or square annular shape and may contact the four sides of the substrate 1.

The main support part 110 may include a first main support frame 111, a second main support frame 112, a third main support frame 113, and a fourth main support frame 114.

The first main support frame 111 and the second main support frame 112 face each other and may extend in the Y-axis direction. The first short side 1Sa of the substrate 1 may be mounted on the first main support frame 111, and the second short side 1Sb of the substrate 1 may be mounted on the second main support frame 112.

The third main support frame 113 and the fourth main support frame 114 face each other and may extend in the X-axis direction. The first long side 1La of the substrate 1 may be mounted on the third main support frame 113, and a portion of the second long side 1Lb of the substrate 1 may be mounted on the fourth main support frame 114.

The length L2 of the third main support frame 113 (or the fourth main support frame 114) may be longer than the length L1 of the first main support frame 111 (or the second main support frame 112). The third main support frame 113 connects one end of the first main support frame 111 with one end of the second main support frame 112, and the fourth main support frame 114 connects the other end of the first main support frame 111 with the other end of the second main support frame 112.

Here, the fourth main support frame 114 has a cutting part 114a, and a sub-support part 210 of a substrate sub-holder 200 may be disposed in or adjacent to the cutting part 114a.

The main lifting part 120 may lift the main support part 110. For example, the main lifting part 120 may move the main support part 110 along a Z-axis direction.

The main lifting part 120 may include a first main lifting part 121, a second main lifting part 122, and a third main lifting part 123. The first main lifting part 121 lifts the first main support frame 111. For example, the first main lifting part 121 may move the first main support frame 111 along the Z-axis direction. The second main lifting part 122 lifts the second main support frame 112, and the third main lifting part 123 lifts the third main support frame 113.

The first main lifting part 121 may include a first main lifting drive motor 1211 and a first main lifting drive shaft 1212. The first main lifting drive motor 1211 may provide a lifting driving force to lift the first main support frame 111. The first main lifting drive shaft 1212 may be connected to the first main lifting drive motor 1211. The first main lifting drive motor 1211 may be disposed in a standby state, and the first main lifting drive shaft 1212 may be disposed in a vacuum state.

Similarly, the second main lifting part 122 may include a second main lifting drive motor 1221 and a second main lifting drive shaft 1222. The second main lifting drive motor 1221 may provide a lifting driving force to lift the second main support frame 112. The second main lifting drive shaft 1222 may be connected to the second main lifting drive motor 1221. The second main lifting drive motor 1221 may be disposed in a standby state, and the second main lifting drive shaft 1222 may be disposed in a vacuum state.

Similarly, a third main lift part 123 may include a third main lift drive motor 1231 and a third main lift drive shaft 1232. The third main lifting drive motor 1231 may provide a lifting driving force to lift the third main support frame 113. The third main lifting drive shaft 1232 may be connected to the third main lifting drive motor 1231. The third main lifting drive motor 1231 may be disposed in a standby state, and the third main lifting drive shaft 1232 may be disposed in a vacuum state.

The substrate sub-holder 200 may support the second long side 1Lb, which is the remaining side among the four sides of the substrate 1. That is, since the substrate 1 is inserted into the chamber body 12 in the Y-axis direction, the first long side 1La is supported by the third main support frame 113, and the second long side 1Lb may be supported by the sub-support part 210.

The substrate sub-holder 200 may include a sub-support part 210, a sub-lifting part 220, and a rotation part 230.

The sub-support part 210 may contact the second long side 1Lb of the substrate 1 and support the second long side 1Lb. The sub-support part 210 may be disposed in the cutting part 114a of the fourth main support frame 114. The sub-support part 210 may include a plurality of contact parts 211 and a sub-support part frame 212. The plurality of contact parts 211 directly contact the second long side 1Lb of the substrate 1, and the sub-support part frame 212 is connected to the plurality of contact parts 211 and extends parallel to the fourth main support frame 114.

The sub-lifting part 220 may lift the sub-supporting part 210. For example, the sub-lifting part 220 may move the sub-supporting part 210 in the Z-axis direction.

The sub-lifting part 220 may include a sub-lifting drive motor 221, a sub-lifting drive shaft 222, and a lifting connection part 223.

The sub-lifting drive motor 221 may provide a lifting driving force to lift the sub-support part 210.

The sub-lifting drive shaft 222 is connected to the sub-lifting drive motor 221 and may extend in the Z-axis direction. The sub-lifting drive motor 221 may be disposed in a standby state, and the sub-lifting drive shaft 222 may be disposed in a vacuum state.

The lifting connection part 223 may connect the sub-support part 210 and the sub-lifting drive shaft 222 to each other.

The lifting connection part 223 may include a lifting connection body 2231 and a lifting bearing 2232.

The lifting connection body 2231 protrudes from the sub-support part frame 212 of the sub-support part 210 and may have a circular rotation hole 2231a.

The lifting bearing 2232 is installed at the end of the sub-lifting drive shaft 222. Further, the lifting bearing 2232 may be inserted into the rotation hole 2231a and rotated.

The rotation part 230 may rotate the sub-support part 210 at a predetermined angle.

The rotation part 230 may include a rotation drive motor 231, a rotation drive shaft 232, and a rotation connection part 233.

The rotation drive motor 231 may provide a rotational driving force to rotate the sub-support part frame 212 of the sub-support part 210 at a predetermined angle.

The rotation drive shaft 232 is connected to the rotation drive motor 231 and may extend in the Z-axis direction.

The rotation connection part 233 may connect the sub-support part 210 and the rotation drive shaft 232 to each other.

The rotation connection part 233 may include the rotation connection body 2331 and a rotation bearing 2332.

The rotation connection body 2331 protrudes from the sub-support part frame 212 of the sub-support part 210 and may have a slit-shaped sliding hole 2331a.

The rotation bearing 2332 is installed at the end of the rotary drive shaft 232 and may be inserted into the sliding hole 2331a to slide therein.

Therefore, the rotation bearing 2332 that is connected to the end of the rotary drive shaft 232 slides within the sliding hole 2331a, and the lifting bearing 2232 that is connected to the end of the sub-lifting drive shaft 222 rotates within the rotation hole 2231a, enabling the sub-support part frame 212 to lift and rotate in a limited narrow space.

Thus, by installing the substrate sub-holder 200 in the cutting part 114a of the fourth support frame 114 of the main support part 110 through which the transport device 20 passes substrate 1 in and out of, it is possible to support the second long side 1Lb of the substrate 1 that is not supported by the main support holder 110, thereby preventing the substrate 1 from sagging.

Additionally, damage to the substrate may be prevented by preventing sagging of the substrate and dispersing concentrated stress.

Additionally, in the process of adsorbing the substrate by using an electrostatic chuck, adsorption failure may be prevented by preventing separation between the electrostatic chuck and the substrate.

Below, the operation of the substrate support apparatus in the deposition system will be described in detail with reference to the drawings.

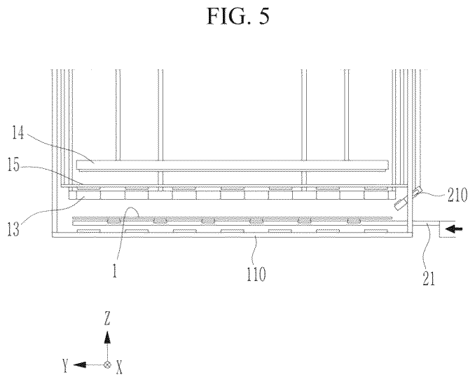

FIG. 5 to FIG. 9 are schematic side views sequentially illustrating the operation of the substrate support apparatus in the deposition system of FIG. 1.

As shown in FIG. 5, the substrate 1, which is mounted on the end effector 21 of the transport device 20, is inserted into the deposition chamber 10 along the Y-axis direction and stops at a position corresponding to the main support holder 110. At this time, the substrate support part 210 of the substrate sub-holder 200 ascends in the Z-axis direction, so it does not interfere with the transport device 20, and thus, the substrate 1 may be introduced into the deposition chamber 10 by using the transport device 20.

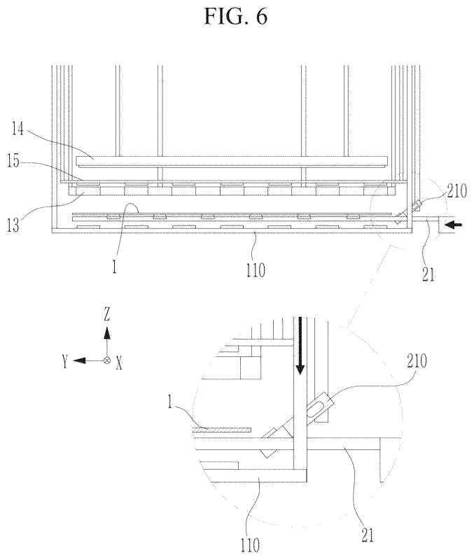

Next, as shown in FIG. 6, the sub-support part 210 of the substrate sub-holder 200 is lowered by the sub-lifting part 220.

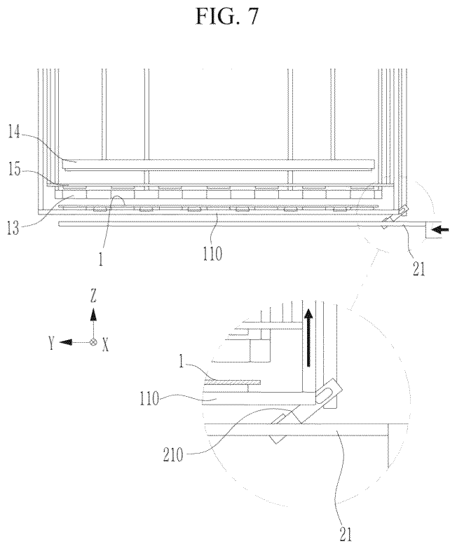

Next, as shown in FIG. 7, the main support part 110 of the substrate main holder 100 is raised to support the first short side 1Sa, the second short side 1Sb, and the first long side 1La of the substrate 1. Then, the main lifting part 120 lifts the substrate 1 while supporting the substrate 1 and separates the substrate 1 from the end effector 21, and the end effector 21 is removed from the substrate support apparatus 30.

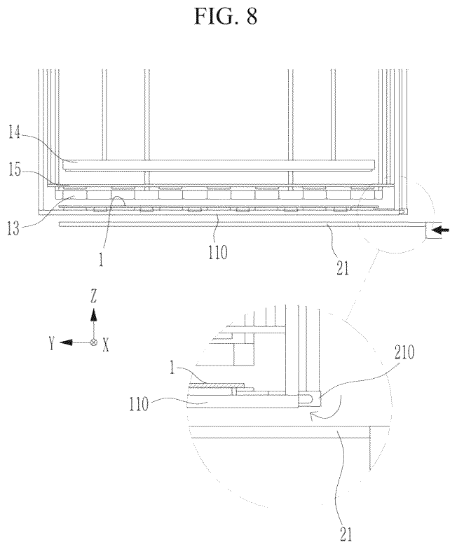

Next, as shown in FIG. 8, the sub-support part 210 is rotated by using the rotation part 230 of the substrate sub-holder 200 so that the sub-support part 210 contacts the second long side 1Lb of the substrate 1 to support the second long side 1Lb of the substrate 1.

In this way, by supporting the four sides of the substrate 1—namely, the first short side 1Sa, the second short side 1Sb, the first long side 1La, and the second long side 1Lb—sagging of the substrate 1 may be prevented.

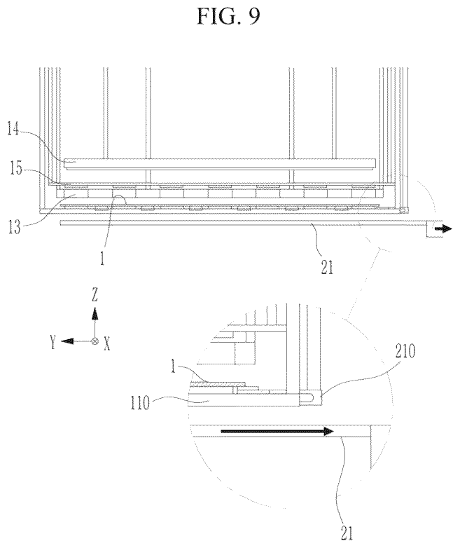

Next, as shown in FIG. 9, the end effector 21 of the transport device 20 is taken out of the chamber main body 12.

While the present invention has been described with reference to exemplary embodiments thereof, it will be understood by those of ordinary skill in the art that various changes in form and details may be made thereto without departing from the spirit and scope of the present invention.

<Description of symbols>

| | |
|---|---|
| 10: deposition chamber | 20: transport device |
| 30: substrate support apparatus | 100: substrate main holder |
| 110: main support part | 120: main lifting part |
| 200: substrate sub-holder | 210: sub-support part |
| 220: sub-lifting part | 230: rotation part |

What is claimed is:

1. A substrate support apparatus, comprising:
a substrate main holder supporting three sides of four sides of a substrate; and
a substrate sub-holder supporting a remaining side of the four sides of the substrate;
wherein the substrate sub-holder comprises:
a sub-support part that contacts the remaining side and supports the remaining side;
a sub-lifting part that moves the sub-support part along a vertical direction; and
a rotation part that rotates the sub-support part at a predetermined angle.

2. The substrate support apparatus of claim 1, wherein:
the three sides of the substrate that are supported by the substrate main holder include a first short side, a second short side, and a first long side, wherein the first short side and the second short side face each other, and the first long side connect the first short side and the second short side to each other, and
the remaining side of the substrate that is supported by the substrate sub-holder includes a second long side facing the first long side.

3. The substrate support apparatus of claim 2, wherein:
the sub-lifting part comprises:
a sub-lifting drive motor that provides a lifting driving force to move the sub-support part along the vertical direction;
a sub-lifting drive shaft connected to the sub-lifting drive motor; and
a lifting connection part connecting the sub-support part and the sub-lifting drive shaft to each other.

4. The substrate support apparatus of claim 3, wherein:
the lifting connection part comprises:
a lifting connection body that protrudes from the sub-support part and has a rotating hole; and
a lifting bearing installed at an end of the lifting drive shaft and inserted into the rotating hole to rotate.

5. The substrate support apparatus of claim 3, wherein:
the rotation part comprises:
a rotation drive motor that provides a rotational driving force to rotate the sub-support part to a predetermined angle;
a rotation drive shaft connected to the rotation drive motor; and
a rotation connection part connecting the sub-support part and the rotation drive shaft to each other.

6. The substrate support apparatus of claim 5, wherein:
the rotation connection part comprises:
a rotation connection body that protrudes from the sub-support part and has a sliding hole; and
a rotation bearing installed at the end of the rotation drive shaft and inserted into the sliding hole to slide within the sliding hole.

7. The substrate support apparatus of claim 6, wherein:
the substrate main holder comprises;
a main support part that has a rectangular or square annular shape and is in contact with the four sides of the substrate; and
a main lifting part that moves the main support part along the vertical direction.

8. The substrate support apparatus of claim 7, wherein:
the main support part comprises:
a first main support frame and a second main support frame facing each other;
a third main support frame that is longer than the first main support frame and connects the first main support frame and the second main support frame to each other; and
a fourth main support frame facing the third main support frame and having a cutting part where the substrate sub-holder is disposed.

9. The substrate support apparatus of claim 8, wherein:
the main lifting part comprises:
a first main lifting part that moves the first main support frame along the vertical direction;
a second main lifting part that moves the second main support frame along the vertical direction; and
a third main lifting part that moves the third main support frame along the vertical direction; and
the first main lifting part and the second main lifting part are disposed facing each other.

10. A deposition system, comprising:
a deposition chamber that performs a deposition process on a substrate;
a transfer device that transfers the substrate into the deposition chamber; and
a substrate support apparatus that supports the substrate that is carried into the deposition chamber by the transfer device,
wherein the substrate support apparatus comprises:
a substrate main holder supporting three sides of four sides of the substrate; and
a substrate sub-holder supporting a remaining side of the four sides of the substrate;
wherein the substrate sub-holder comprises:
a sub-support part that contacts the remaining side and supports the remaining side;
a sub-lifting part that moves the sub-support part along a vertical direction; and
a rotation part that rotates the sub-support part at a predetermined angle.

11. The deposition system of claim 10, wherein:
the three sides of the substrate that are supported by the substrate main holder include a first short side, a second short side, and a first long side, wherein the first short side and the second short side face each other, and the first long side connects the first short side and the second short side to each other, and
the remaining side of the substrate that is supported by the substrate sub-holder includes a second long side facing the first long side.

12. The deposition system of claim 11, wherein:
the sub-lifting part comprises:
a sub-lifting drive motor that provides a lifting driving force to move the sub-support part along the vertical direction;
a sub-lifting drive shaft connected to the sub-lifting drive motor; and
a lifting connection part connecting the sub-support part and the sub-lifting drive shaft to each other.

13. The deposition system of claim 12, wherein:
the lifting connection part comprises:
a lifting connection body that protrudes from the sub-support part and has a rotation hole; and
a lifting bearing installed at an end of the sub-lifting drive shaft and inserted into the rotation hole to rotate.

14. The deposition system of claim 12, wherein:
the rotation part comprises:
a rotation drive motor that provides a rotational driving force to rotate the sub-support part to a predetermined angle;
a rotation drive shaft connected to the rotation drive motor; and
a rotation connection part connecting the sub-support part and the rotation drive shaft to each other.

15. The deposition system of claim 14, wherein:
the rotation connection part comprises:
a rotation connection body that protrudes from the sub-support part and has a sliding hole; and
a rotation bearing installed at end of the rotation drive shaft and inserted into the sliding hole to slide within the sliding hole.

16. The deposition system of claim 11, wherein:
the substrate main holder comprises:
a main support part that has a rectangular or square annular shape and is in contact with the four sides of the substrate; and
a main lifting part that moves the main support part along the vertical direction,
the main support part comprises:
a first main support frame and a second main support frame facing each other;
a third main support frame that is longer than the first main support frame and connects the first main support frame and the second main support frame to each other; and
a fourth main support frame facing the third main support frame and having a cutting part where the substrate sub-holder is disposed.

17. The deposition system of claim 16, wherein:
the main lifting part comprises:
a first main lifting part that moves the first main support frame along the vertical direction;
a second main lifting part that moves the second main support frame along the vertical direction; and
a third main lifting part that moves the third main support frame along the vertical direction, and
the first main lifting part and the second main lifting part are disposed facing each other.

18. The deposition system of claim 17, wherein:
the first main lifting part includes a first main lifting drive motor and a first main lifting driving shaft, wherein the first main lifting drive motor provides a lifting driving force to raise and lower the first main support frame, wherein the first main lifting drive shaft is connected to the first main lifting drive motor, and
the second main lifting part includes a second main lifting drive motor and a second main lifting drive shaft, wherein the second main lifting drive motor provides a lifting driving force to raise and lower the second main support frame, wherein the second main lifting drive shaft is connected to the second main lifting drive motor.

19. The deposition system of claim 17, wherein:
an end effector of the transfer device carries the substrate through the cutting part,
the main support part supports the first short side, the second short side, and the first long side of the substrate, and the main lifting part moves the substrate along the vertical direction, and
the sub-support part supports a second long side of the substrate, and the sub-lifting part and the rotation part move the sub-support part to come into contact the second long side of the substrate.

20. A deposition system, comprising:
a deposition chamber that performs a deposition process on a substrate; and
a substrate support apparatus that supports the substrate that is within the deposition chamber,
wherein the substrate support apparatus comprises:
a substrate main holder supporting three sides of four sides of the substrate; and
a substrate sub-holder supporting a remaining side of the four sides of the substrate;
wherein the substrate sub-holder comprises:
a sub-support part that supports the remaining side of the substrate;
a sub-lifting part that moves the sub-support part along a vertical direction; and
a rotation part connected to the sub-support part and rotating the sub-support part,
wherein the sub-lifting part comprises:
a sub-lifting drive motor that moves the sub-support part along the vertical direction; and
a sub-lifting drive shaft connected to the sub-lifting drive motor and the sub-support part,
wherein the rotation part comprises:
a rotation drive motor that provides a rotational driving force to rotate the sub-support part to a predetermined angle; and
a rotation drive shaft connected to the rotation drive motor and the sub-support part.
